(19) United States
(12) Patent Application Publication
(10) Pub. No.: US 2025/0297366 A1
(43) Pub. Date: Sep. 25, 2025

(54) MICROWAVE PLASMA-ENHANCED CHEMICAL VAPOR DEPOSITION DEVICE

(71) Applicant: Tsun Kwan YEUNG, Hong Kong (HK)

(72) Inventor: Tsun Kwan YEUNG, Hong Kong (HK)

(21) Appl. No.: 18/616,133

(22) Filed: Mar. 25, 2024

(51) Int. Cl. C23C 16/511; C23C 16/448; C23C 16/455; C23C 16/52

(52) U.S. Cl. CPC C23C 16/511; C23C 16/4488; C23C 16/45561; C23C 16/52

(57) ABSTRACT

A Microwave Plasma-enhanced Chemical Vapor Deposition (MPCVD) Device is provided. The MPCVD device comprises a reacting chamber and a gas generator. The reacting chamber contains a substrate holder. The gas generator provides hydrogen to the reacting chamber. The purity of the hydrogen is higher than 4N. The reacting chamber is configured to facilitate a MPCVD process, and the gas generator is at the site of the MPCVD process.

### FIELD OF THE INVENTION

The present invention generally relates to chemical vapor deposition apparatus. More specifically the present invention relates to microwave plasma-enhances chemical vapor deposition (MPCVD) device.

### BACKGROUND OF THE INVENTION

Chemical Vapor Deposition (CVD) is a versatile and widely employed process in material science and engineering, used for the synthesis of thin films and coating on various substrates. The fundamental principle involves the deposition of materials from vapor phase precursors onto a substrate surface, forming a thin, uniform layer. This technique finds applications across diverse industries, including electronics, where it is utilized in the fabrication of semiconductor devices and integrated circuits, as well as in optics for coating lenses and mirrors. Additionally, CVD is employed in the production of cutting tools, creating durable and wear-resistant coatings that enhance tool performance.

MPCVD represents a specialized variation of traditional CVD, incorporating microwave-generated plasma to enhance the deposition process. The addition of microwave energy allows for greater control over reaction kinetics, resulting in improved film quality and increased deposition rates. MPCVD is particularly advantageous in the synthesis of thin films for electronic applications, as it enables precise tuning of material properties. The use of microwave plasma enhances the activation of precursors, leading to improved film adhesion and reduced defects, making it a preferred technique for advanced electronic devices.

While CVD offers unparalleled versatility, it is not without challenges. The process is characterized by low efficiency, high cost, and limited scalability. The inefficiency arises from the incomplete utilization of precursor materials, leading to wastage and increased production costs. Moreover, the intricate instrumentation and stringent process control requirements contribute to elevated operational expenses. Scalability issues stem from the intricate control needed for uniform and reproducible coatings over large areas, posing a barrier to cost-effective mass production. Researchers and engineers continue to address these challenges to unlock the full potential of CVD in diverse industrial applications. Therefore, there is a need for an efficient and cost-effective solution for thin-film materials manufacture.

### SUMMARY OF THE INVENTION

It is an objective of the present invention to provide a system to address the aforementioned shortcomings and unmet needs in the current state of the art. The present invention provides an MPCVD device having a reacting chamber and a gas generator located at the same site. The advantages of the device include: improved efficiency, enhanced quality, wild-ranging applications, and marketability, providing a cost-effective solution to improve production performance and quality.

In accordance with a first aspect of the present invention, a MPCVD device is provided. The MPCVD device includes a reacting chamber, and a gas generator. The reacting chamber contains a substrate holder. The gas generator provides hydrogen to the reacting chamber. The purity of the hydrogen is higher than 4N. The reacting chamber is configured to facilitate a MPCVD process, and the gas generator is at the site of the MPCVD process.

In accordance with one embodiment of the present invention, the gas generator comprises a water electrolyzer, and an outlet of the water electrolyzer is connected to the reacting chamber.

In accordance with another embodiment, the water electrolyzer comprises a proton exchange membrane.

In accordance with another embodiment, the MPCVD device further comprises a palladium purifier. The palladium purifier connects the gas generator with the reacting chamber.

In accordance with another embodiment, the MPCVD device further comprises a gas delivery device. The gas delivery device connects the reacting chamber and the gas generator.

In accordance with another embodiment, the length of the gas delivery device is less than 3 metres.

In accordance with another embodiment, the MPCVD device further comprising a microwave generator, and the microwave generator is connected to the reacting chamber.

In accordance with another embodiment, the microwave generator is configured to generate a microwave, and the frequency of the microwave ranges from 800 MHz to 2.8 GHz.

In accordance with another embodiment, the MPCVD device further comprises a control device. The control device is connected to the reacting chamber and the gas generator.

In accordance with another embodiment, the control device controls a flow rate of the hydrogen, and the control device controls a temperature and a pressure of the reacting chamber, and the flow rate ranges from 50 sccm to 1500 sccm, and the temperature ranges from 100 to 1600 degree Celsius, and the pressure ranges from 10 to 760 Torr.

In accordance with another embodiment, the MPCVD device further comprises a sealing container, and the reacting chamber and the gas generator are disposed in the sealing container.

In accordance with another embodiment, the MPCVD device further comprises a condenser. The gas generator provides oxygen, and the condenser connects the gas generator to the reacting chamber.

In summary, the MPCVD device of the embodiments of the present invention achieve efficient and cost-effective thin-film manufacture. The MPCVD device can provide high-quality thin-film material with proper thickness, uniformity, and the impurities are reduced.

### BRIEF DESCRIPTION OF THE DRAWINGS

Embodiments of the invention are described in more details hereinafter with reference to the drawings, in which:

FIG. 1 depicts a schematic view of a MPCVD device in accordance with an embodiment of the present invention;

FIG. 2 depicts a schematic view of a MPCVD device in accordance with another embodiment of the present invention; and

FIG. 3 depicts a schematic view of a MPCVD device in accordance with still another embodiment of the present invention.

### DETAILED DESCRIPTION

In the following description, a MPCVD device and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

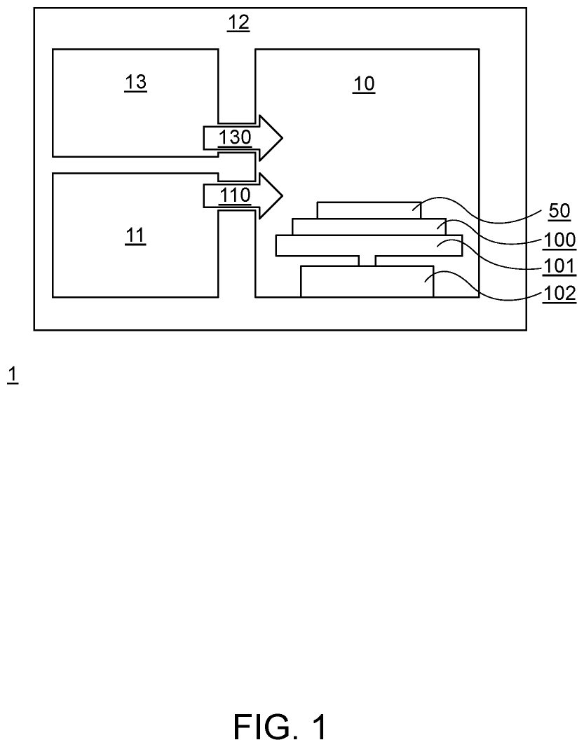

FIG. 1 is a schematic drawing of a MPCVD device 1 of an embodiment. In this embodiment, The MPCVD device 1 has a reacting chamber 10 and a gas generator 11, and the gas generator 11 is sitting next to the reacting chamber 10. In other words, the gas generator 11 is located near the reacting chamber 10.

The reacting chamber 10 contains a substrate holder 100, and the substrate holder 100 is adapted to carry a substrate 50. In some embodiments, the substrate 50 is made of single crystal silicon. In some other embodiments, the substrate 50 can include non-silicon material such as Tungsten, molybdenum, titanium, or ceramic.

In the embodiment referring to FIG. 1, the gas generator 11 provides the hydrogen 110 to the reacting chamber 10, and the purity of the hydrogen 110 is higher than 4N. The MPCVD device 1 incorporates the reacting chamber 10 and the closely positioned gas generator 11 supplying high-purity hydrogen 110. Notably, both the gas generator 11 and the reacting chamber 10 are spatially co-located within the same room, ensuring optimal proximity for the efficient execution of the MPCVD process. Also, the gas generator 11 of this embodiment provide the hydrogen 110 as well as other gas with ensured uniformity, eliminating the problem from using varied gas supplies from different vendors, which have different impurities.

In this embodiment, the reacting chamber 10 receives the hydrogen directly from the gas generator 11 through short passage, which eliminates the risk of leaks from long gas supply line, gas storage, and the risk of impurities absorption from internal of long gas tube. The MPCVD device 1 provides a turnkey solution with a preset production recipe, and less training is needed for operating the MPCVD device 1.

In another embodiment, the reacting chamber 10 and the gas generator 11 are housed within the same chamber. The intentional arrangement of the gas generator 11 and the reacting chamber 10 in close proximity ensures a seamless MPCVD process, with both components strategically positioned for enhanced operational efficiency.

In still another embodiment, positioned on the same table for streamlined operation, the MPCVD device 1 consists of the reacting chamber 10 incorporating the substrate holder 100 and the gas generator 11 providing hydrogen 110 with a purity level surpassing 4N. The deliberate co-location of the gas generator 11 and reacting chamber 10 underscores their physical proximity, fostering an integrated and efficient MPCVD process.

In these embodiments, the MPCVD device 1 described presents a notable advancement in thin film manufacturing, particularly through its emphasis on efficiency in the MPCVD approach. By strategically sitting the gas generator 11 in close proximity to the reacting chamber 10 within the same operation space, the device 1 optimizes the delivery and utilization of high-purity hydrogen. This design facilitates a seamless MPCVD process, minimizing material wastage and improving overall operational efficiency. The configuration ensures that the hydrogen, with a purity exceeding 4N, is readily available at the MPCVD process site, enhancing the quality of thin film deposition. The deliberate co-location of the essential components on the same table or within the same chamber streamlines the overall manufacturing process, making the MPCVD device 1 a promising tool for cost-effective and resource-efficient thin film production.

Referring to FIG. 1, the MPCVD device 1 further comprises a sealing container 12. The reacting chamber 10 and the gas generator 11 are disposed in the sealing container 12.

The sealing container 12 provide an ideal environment for the reacting chamber 10 and the gas generator 11 by controlling the air purity, temperature, or pressure. After inserting the substrate 50 and the hydrogen feedstock, the sealing container 12 is sealed, creating an ideal environment for MPCVD process, thereby further reducing impurities.

In this embodiment, the MPCVD device 1 has a microwave generator 13. The microwave generator 13 is connected to the reacting chamber 10, and the microwave generator 13 is located near the gas generator 11. Therefore, the MPCVD device 1 can provide a seamless MPCVD process with these components.

In this embodiment, the microwave generator 13 can include Magnetrons. In some other embodiments, the microwave generator 13 can include other device that is configured to generate microwave to the reacting chamber 10.

The microwave generator 13 of this embodiment is configured to produce microwave 130 with a frequency ranging from 800 MHz to 2.8 GHz. This frequency range encompasses values corresponding to the resonant frequency of molecular vibrations in water molecules, which include hydrogen. The microwave energy is absorbed by the gas, causing ionization and the formation of a high-energy plasma state, essential for the MPCVD process.

For other details of these embodiments, the reacting chamber 10 comprises a heating plate 101 and a controller 102. The heating plate 101 carries the substrate holder 100, and controls the temperature of the substrate holder 100. The controller 102 monitors and adjust the temperature of the heating plate 101, and control the altitude of the substrate holder 100 as well.

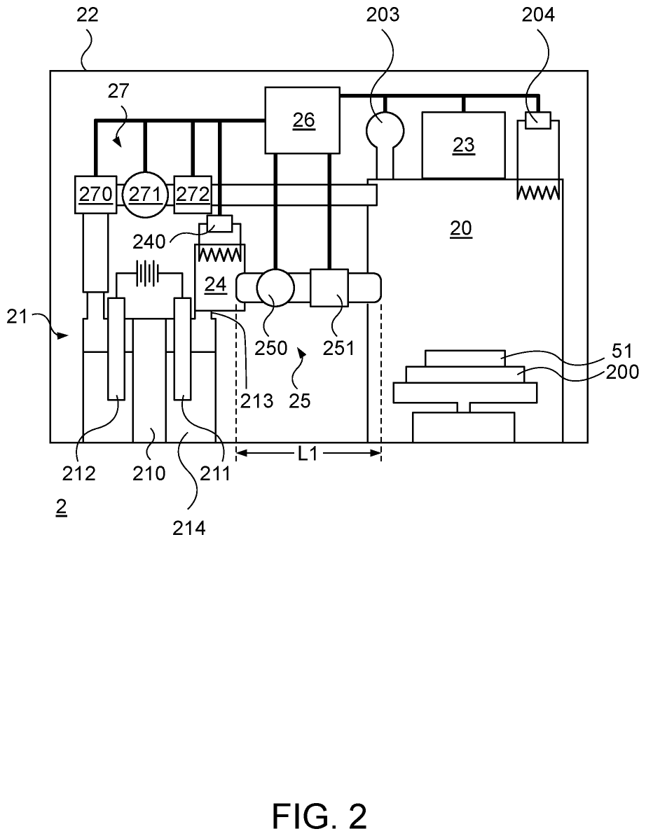

FIG. 2 is a schematic drawing of a MPCVD device 2 of another embodiment. In this embodiment, the MPCVD device 2 has a reacting chamber 20, a gas generator 21, a sealing container 22, a microwave generator 23, a palladium purifier 24, a gas delivery device 25, and a control device 26. The reacting chamber 20 has a substrate holder 200 which is adapted to carry a substrate 51. The reacting chamber 20 is configured to facilitate a MPCVD process with the microwave generator 23 and the gas generator 21, and the gas generator 21 is at the site of the MPCVD process. In other words, the reacting chamber 20 and the gas generator 21 are sealed by the sealing container 22.

In this embodiment, the gas generator 21 comprises a water electrolyzer, and an outlet 213 of the gas generator 21 is connected to the reacting chamber 20. The water electrolyzer is sealed in the sealing container 22 with the reacting chamber 20, and distance between the water electrolyzer and the reacting chamber 20 is short, and the environment is well protected by the sealing container 22. Therefore, the MPCVD process generated by the MPCVD device 2 is improved by the water electrolyzer at the site.

The water electrolyzer of this embodiment has a proton exchange membrane (PEM) 210. The PEM 210 in the water electrolyzer is a critical component that facilitates the electrochemical process of water splitting into hydrogen and oxygen. Comprising a polymer electrolyte, often Nafion, the PEM 210 selectively conducts protons (H⁺ ions) while preventing the passage of electrons. Placed between the anode 212 and cathode 211 compartments, the PEM 210 ensures the separation of hydrogen and oxygen evolution reactions, allowing for controlled proton transport. This selective ion conduction enables the efficient and targeted migration of protons from the anode to the cathode, where they combine with electrons and oxygen to form water. The PEM's 210 high proton conductivity is pivotal in achieving optimal electrolyzer performance, ensuring the production of high-purity hydrogen gas. In this embodiment, the PEM type water electrolyzer in gas generator 21 provide hydrogen gas with purity exceeding 4N. For example, the water electrolyzer in this embodiment provide hydrogen gas with purity ranges from 4N to 5N.

Additionally, the PEM's robustness and chemical stability contribute to the durability and longevity of the electrolyzer system, making it a key feature for the successful and sustained operation of proton exchange membrane water electrolyzer.

In this embodiment, the palladium purifier 24 receives hydrogen gas generated by the water electrolyzer, and a pump or compressor is installed in the passage of the input of the palladium purifier 24. The palladium purifier 24 operates through pressure-driven diffusion across palladium membranes. Only hydrogen can diffuse through the palladium diffuser, which may take various forms such as array of tubes, a coiled tube, or membrane foil. Notably, the palladium purifier 24 is seamlessly integrated into the system, establishing a direct connection with the outlet 213 of the compartment housing the cathode 211. This compartment is immersed in deionized water 214, underscoring the strategic placement of the purifier in the post-electrolysis process.

The palladium purifier 24, integral to the water electrolyzer, plays a pivotal role in enhancing the purity of the generated hydrogen gas. As hydrogen flows through the purifier 24, impurities and undesired elements are selectively absorbed by the palladium membrane, resulting in a substantial improvement in the overall purity of the gas. The unique properties of palladium, including its high affinity for impurities, enable effective purification, leading to hydrogen gas with an exceptional purity level. In this specific embodiment, the purity of the hydrogen gas emerging from the palladium purifier 24 ranges from 7N to 9N, attesting to the efficiency of the purifier in achieving a high degree of gas refinement.

The palladium purifier 24 of this embodiment has a heat controller 240, which monitor and control the temperature of the palladium purifier 24. The implementation of precise temperature control in the palladium purifier 24 offers a myriad of advantages in optimizing its performance. Maintaining a controlled temperature within the purifier is paramount as it directly influences the efficiency of hydrogen purification. By carefully regulating the temperature, the adsorption and desorption processes on the palladium surface can be fine-tuned, ensuring optimal purification without compromising the structural integrity of the purifier. Moreover, temperature control contributes to the longevity of the palladium membrane, minimizing wear and tear associated with extreme temperature variations. This level of control allows for a consistent and reliable purification process, resulting in hydrogen gas of consistently high purity. Additionally, temperature modulation facilitates adaptability to varying operational conditions, making the palladium purifier 24 a versatile component in hydrogen production systems where precise gas quality is essential.

The gas delivery device 25 of the MPCVD device 2 of this embodiment connects the reacting chamber 20 and the gas generator 21.

In the context of the MPCVD device 2, the gas delivery device 25 serves as a crucial component connecting the reacting chamber 20 and the gas generator 21. This device not only facilitates the seamless transportation of gases between these key elements but also incorporates advanced features to enhance operational control. Specifically, the gas delivery device 25 is equipped with precision controls for regulating both the flow rate and pressure of the gases. This capability allows for meticulous adjustments in the deposition process, ensuring optimal conditions for the chemical vapor deposition reactions within the reacting chamber 20. The integration of this sophisticated gas delivery system not only streamlines the MPCVD process but also enhances its versatility, making it well-suited for a range of applications where precise control over gas flow and pressure is imperative for achieving high-quality thin film deposition.

To be specific, the length L1 of the gas delivery device 25 is less than 3 metres. Therefore, the gas delivery device 25 connect the gas generator 21 and the reacting chamber and keep them close to each other.

The gas delivery device 25 plays a critical role in the MPCVD device 2 by establishing a direct connection between the gas generator 21 and the reacting chamber 20, ensuring their close proximity. This design facilitates the prompt delivery of high-purity hydrogen to the reacting chamber 20, optimizing the efficiency of the chemical vapor deposition process. Notably, the gas delivery device's compact design contributes to enhanced control over gas flow, pressure, and temperature. This level of control is especially advantageous when compared to the challenges associated with long-distance pipe connections, enabling precise adjustments and minimizing potential fluctuations in the deposition conditions.

Furthermore, the distance between the cathode 211 and the substrate holder 200 in some embodiments is less than 3 metres, so as to perform a seamless MPCVD process.

The control device 26 of this embodiment is connected to the reacting chamber 20 and the gas generator 21. The MPCVD device 2 incorporates a sophisticated control device 26 that serves as the nexus between the reacting chamber 20 and the gas generator 21, orchestrating simultaneous control over both components. This centralized control mechanism enables seamless coordination between the reacting chamber 20 and the gas generator 21, facilitating precise adjustments to various operational parameters. The control device 26 exhibits a comprehensive range of functionalities, allowing for real-time manipulation of factors such as gas flow rates, pressure, and temperature. Its advanced interface ensures synchronized operation, contributing to the optimization of the entire MPCVD process. This feature not only enhances efficiency but also provides a user-friendly platform for operators to customize and monitor deposition conditions, ultimately resulting in improved control and reproducibility in thin film manufacturing.

In this embodiment, the control device 26 controls a flow rate of the hydrogen, and the control device 26 controls a temperature and a pressure of the reacting chamber 20. The flow rate ranges from 50 sccm to 1500 sccm, and the temperature ranges from 100 to 1600 degree Celsius, and the pressure ranges from 10 to 760 Torr.

The range encompassed by these values is well-suited for applications like diamond deposition, where precision is paramount. The thin-film materials, especially diamond, produced under these conditions exhibit superior characteristics, including finely tuned thickness, uniformity, and diminished impurity levels. This combination of specific parameters ensures the optimal conditions for the synthesis of high-quality thin films, making the process particularly advantageous for applications that demand exacting standards, such as diamond deposition. Also, in such condition, the MPCVD device 2 can apply deposition of graphene as well, and both the single layer graphene and the multilayer graphene can be done through the MPCVD device 2.

In the embodiment referring to FIG. 2, the palladium purifier 24 has a temperature controller 240, and the gas delivery device 25 has a pressure controller 250 and a temperature controller 251, and the reacting chamber 20 has a pressure controller 203 and a temperature controller 204. The control device 26 is connected to the temperature controller 240, 251, 204 and the pressure controllers 250, 203.

Furthermore, the MPCVD device 2 further includes a gas delivery device 27. The gas delivery device 27 has a condenser 270, a pressure controller 271, and a temperature controller 272. The gas generator 21 produce oxygen from the compartment which accommodates the anode 212, and the condenser 270 removes water vapor from the compartment. Therefore, the MPCVD device 2 of this embodiment can utilize high purity oxygen in MPCVD process. The control device 26 is connected to the condenser 270, the pressure controller 271, and the temperature controller 272, and the gas delivery device 27 may provide oxygen with flow rate ranges between 5 sccm to 50 sccm.

The control device 26 serves as a central hub, connecting the temperature controllers, pressure controllers, and the microwave source 23 in the MPCVD system. This integrated configuration empowers the control device 26 to oversee a majority of the pivotal parameters crucial for the MPCVD process. By effectively managing temperature, pressure, and microwave energy, the control device 26 plays a pivotal role in optimizing the overall quality and yield of the MPCVD process, ensuring precise control and coordination of essential parameters for enhanced deposition outcomes.

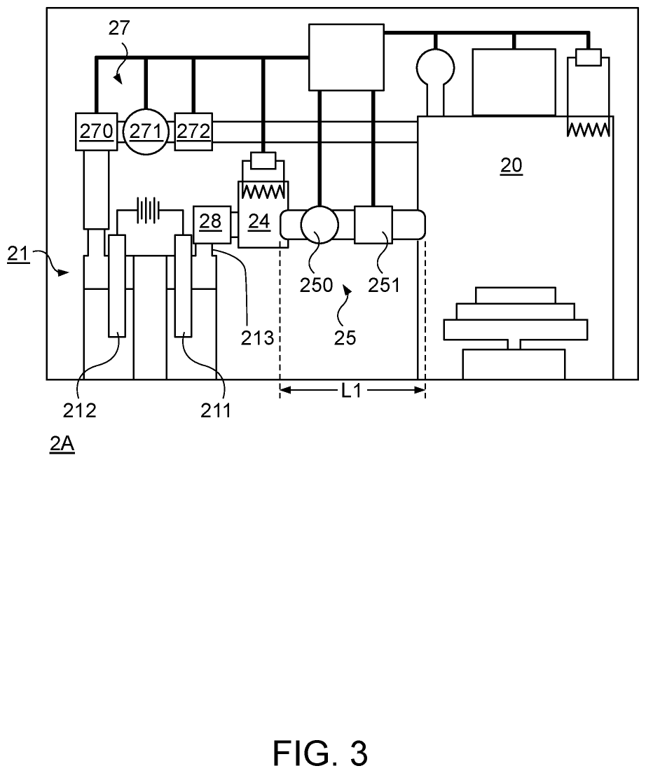

The MPCVD device of some embodiments of the present invention comprises another condenser for hydrogen. FIG. 3 is a schematic drawing of a MPCVD device 2A of still another embodiment. The MPCVD device 2A has the reacting chamber 20, the gas generator 21, the gas delivery device 25, and the gas delivery device 27. The gas delivery device 25 connects the gas generator 21 and the reacting chamber 20 and provide a tube for transferring hydrogen, and the gas deliver device 27, which also connects the gas generator 21 and the reacting chamber 20, provides another transferring tube for oxygen or any other gas from gas generator 21.

The gas delivery device 27 of this embodiment has the condenser 270, the pressure controller 271, and the temperature controller 272, so as to control the humidity, the pressure, and the temperature of the gas transferring through the gas delivery device 27.

The MPCVD device 2A of this embodiment has the palladium purifier 24 and a condenser 28. The palladium purifier 24 connects the condenser 28 and the gas delivery device 25, and the condenser 28 connects the gas generator 21 and the palladium purifier 24. The MPCVD device 2A can control the humidity, the pressure, and the temperature of the gas transferring through the gas delivery device 25 through the condenser 28, the pressure controller 250, and the temperature controller 25.

The condenser 270 is connected to the compartment housing the anode 212 in the gas generator 21, and the condenser 28 is connected to the compartment housing the cathode 211 in the gas generator 21, so as to remove water vapor from all the gas provided by the gas generator 21. Moreover, the condenser 28 removes the water vapor from the gas contains hydrogen before the gas enters the palladium purifier 24, which prolong the lifetime of the palladium purifier 24 as well as the MPCVD device 2A.

The MPCVD device of these embodiments incorporates a gas generator and reacting chamber at a consolidated site, strategically designed to elevate the purity of hydrogen. This innovative configuration empowers the MPCVD device to execute a proficient and cost-effective manufacturing process for the production of premium thin-film materials characterized by precise thickness control, uniformity, and minimized impurities.

A notable advantage of the MPCVD device is its improved efficiency. The on-site water electrolyzer generates high-purity hydrogen and oxygen, contributing to the controlled gas purity that, in turn, enhances the reliability and consistency of CVD processes. Additionally, this streamlined process results in a notable reduction in overall costs, making it an economically sound choice.

Furthermore, the MPCVD device ensures enhanced material quality through elevated surface functionalities and improved mechanical properties. This commitment to superior quality extends its applicability across a spectrum of industries, including microelectronics, optoelectronics, nanotechnology, biomedicine, and renewable energy.

The device's wide-ranging applications underscore its adaptability, showcasing potential across diverse industries. This versatility positions the MPCVD device as a valuable asset for those seeking advanced manufacturing solutions.

From a marketability standpoint, the MPCVD device's integrated design offers a cost-effective solution, thereby enhancing both production performance and material quality. Its efficiency and adaptability make it an attractive option for various industrial applications, further solidifying its appeal in the market.

In summary, the MPCVD device's integration of a gas generator and reacting chamber not only optimizes hydrogen purity but also brings forth tangible benefits such as improved efficiency, superior material quality, broad applications, and heightened market appeal.

All or portions of the methods in accordance to the embodiments may be executed in one or more computing devices including server computers, personal computers, laptop computers, mobile computing devices such as smartphones and tablet computers.

The embodiments may include computer storage media, transient and non-transient memory devices having machine instructions stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. A Microwave Plasma-enhanced Chemical Vapor Deposition (MPCVD) Device, comprising:
a reacting chamber containing a substrate holder; and
a gas generator providing hydrogen to the reacting chamber,
wherein a purity of the hydrogen is higher than 4N,
wherein the reacting chamber is configured to facilitate a MPCVD process, and the gas generator is at the site of the MPCVD process.

2. The MPCVD device of claim 1, wherein the gas generator comprises a water electrolyzer, and an outlet of the water electrolyzer is connected to the reacting chamber.

3. The MPCVD device of claim 2, wherein the water electrolyzer comprises a proton exchange membrane.

4. The MPCVD device of claim 1 further comprising a palladium purifier, wherein the palladium purifier connects the gas generator with the reacting chamber.

5. The MPCVD device of claim 1 further comprising a gas delivery device, wherein the gas delivery device connects the reacting chamber and the gas generator.

6. The MPCVD device of claim 1, wherein the length of the gas delivery device is less than 3 metres.

7. The MPCVD device of claim 1 further comprising a microwave generator, wherein the microwave generator is connected to the reacting chamber.

8. The MPCVD device of claim 7, wherein the microwave generator is configured to generate a microwave, and the frequency of the microwave ranges from 800 MHz to 2.8 GHz.

9. The MPCVD device of claim 1 further comprising a control device, wherein the control device is connected to the reacting chamber and the gas generator.

10. The MPCVD device of claim 1, wherein the control device controls a flow rate of the hydrogen, and the control device controls a temperature and a pressure of the reacting chamber, and the flow rate ranges from 50 sccm to 1500 sccm, and the temperature ranges from 100 to 1600 degree Celsius, and the pressure ranges from 10 to 760 Torr.

11. The MPCVD device of claim 1 further comprising a sealing container, wherein the reacting chamber and the gas generator are disposed in the sealing container.

12. The MPCVD device of claim 1 further comprising a condenser, wherein the gas generator provides oxygen, and the condenser connects the gas generator to the reacting chamber.
